(19) United States
(12) Patent Application Publication
(10) Pub. No.: US 2022/0399234 A1
(43) Pub. Date: Dec. 15, 2022

(54) SEMICONDUCTOR DIE SINGULATION

(71) Applicant: NXP B.V., San Jose, CA (US)

(72) Inventors: WeiCheng Chuang, Kaohsiung City (TW); PaoTung Pan, Kaohsiung City (TW); Che Lun Cheng, Kaohsiung City (TW); Yao Jung Chang, Kaohsiung (TW); Yu-Wen Chu, Kaohsiung City (TW); Chun-Hui Lee, Kaohsiung City (TW); Che-Kai Hsu, Kaohsiung City (TW); Kuan Lin Huang, Changhua City (TW)

(21) Appl. No.: 17/347,843

(22) Filed: Jun. 15, 2021

(51) Int. Cl. H01L 21/78; H01L 21/268; H01L 21/304; H01L 21/683; H01L 23/544; H01L 23/00; H01L 23/58

(52) U.S. Cl. CPC H01L 21/78; H01L 21/268; H01L 21/3043; H01L 21/6836; H01L 23/544; H01L 23/562; H01L 23/564; H01L 23/585; H01L 2221/68327; H01L 2223/5446

(57) ABSTRACT

A method of semiconductor die singulation is provided. The method includes forming a first trench along a singulation lane of a semiconductor wafer. A second trench is formed extending from a bottom of the first trench. A portion of the semiconductor wafer remains between a bottom of the second trench and a backside of the semiconductor wafer. A cut is formed by way of a laser to singulate die of the semiconductor wafer. The cut extends through the portion of the semiconductor wafer remaining between the bottom of the second trench and the backside of the semiconductor wafer.

### BACKGROUND

### Field

This disclosure relates generally to semiconductor device packaging, and more specifically, to semiconductor die singulation.

### Related Art

Semiconductor devices are often found in a large spectrum of electronic products—from sewing machines to washing machines, from automobiles to cellular telephones, and so on. Many of these semiconductor devices are produced in high volumes to drive costs down. Factors such as manufacturing processes may be optimized for high volumes but could adversely affect yield and reliability thus impacting product costs. As technology progresses, semiconductor manufacturers continue to seek ways to improve yield and reliability in these semiconductor devices while keeping product costs in focus.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates, in a simplified plan view, an example semiconductor wafer at a final stage of manufacture in accordance with an embodiment.

FIG. 2 illustrates, in a simplified cross-sectional views, the example semiconductor wafer at the stage of manufacture depicted in FIG. 1 in accordance with an embodiment.

FIG. 3 illustrates, in a simplified cross-sectional views, the example semiconductor wafer at a stage of die singulation in accordance with an embodiment.

FIG. 4 illustrates, in a simplified cross-sectional views, the example semiconductor wafer at subsequent stage of die singulation in accordance with an embodiment.

FIG. 5 illustrates, in a simplified cross-sectional views, the example semiconductor wafer at subsequent stage of die singulation in accordance with an embodiment.

### DETAILED DESCRIPTION

Generally, there is provided, a semiconductor die singulation method and apparatus for improving yield and reliability. A first trench is formed at the active side of a semiconductor wafer along singulation lanes between adjacent semiconductor die. The first trench is formed by way of an ultra-short pulse (USP) laser during a first laser ablation operation. A second trench is formed along the singulation lanes of the semiconductor wafer by way of a mechanical saw during a sawing operation. A portion of the semiconductor wafer along the singulation lanes remaining between a bottom of the second trench and backside of the wafer is removed by way of a final laser cut. The final laser cut is formed by way of an USP laser configured with a narrower laser beam during a second laser ablation operation to complete the singulation process. By completing the singulation process with the second laser ablation operation, mechanical sawing is limited to an intermediate region of the semiconductor wafer thickness thus preventing mechanical damage to the active side and backside of the plurality of singulated semiconductor die. Accordingly, yield and reliability are improved.

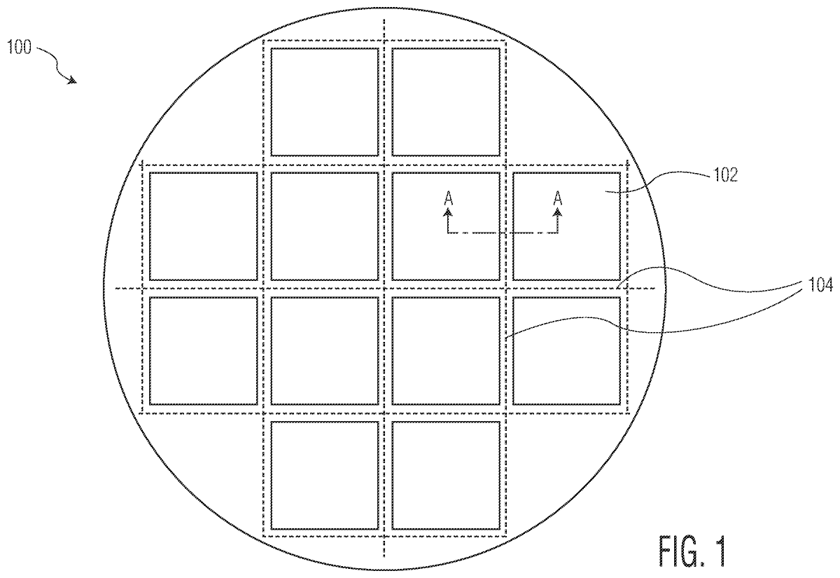

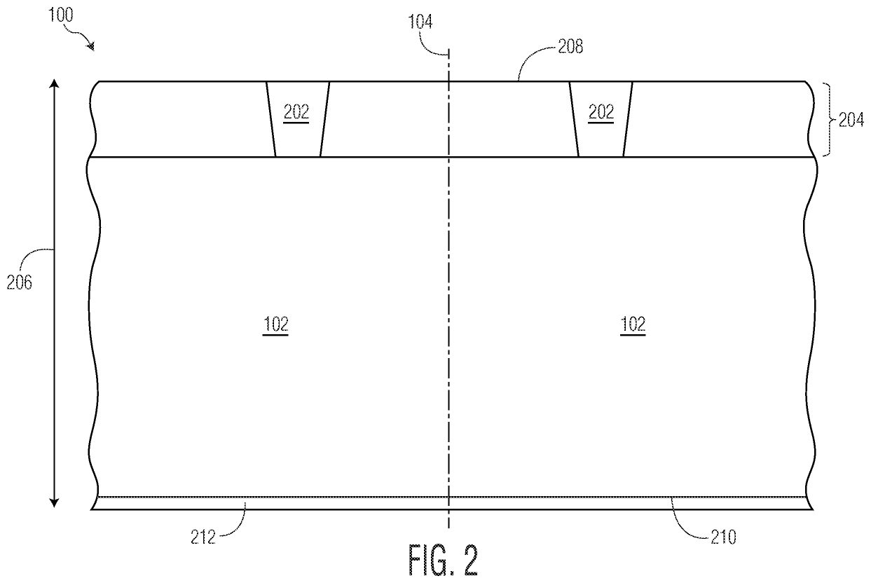

FIG. 1 illustrates, in a simplified plan view, an example semiconductor wafer 100 at a final stage of manufacture in accordance with an embodiment. At this stage of manufacture, the semiconductor wafer 100 has completed a fabrication process and is ready for die singulation. The semiconductor wafer 100 includes a plurality of semiconductor die 102 separated by a predetermined grid of singulation lanes 104 shown as dashed lines. In this embodiment, the semiconductor wafer 100 is depicted having 12 semiconductor die 102, for example. The number and size of the semiconductor die 102 of the semiconductor wafer 100 are chosen for illustration purposes. Cross-sectional views of examples of the semiconductor wafer 100 taken along line A-A at stages die singulation are depicted in FIG. 2 through FIG. 5.

The semiconductor wafer 100 has an active side (e.g., major side having circuitry of the semiconductor die 102) and a backside (e.g., major side opposite of the active side). The semiconductor wafer 100 may be formed from any suitable semiconductor material, such as silicon, germanium, gallium arsenide, gallium nitride and the like. The semiconductor die 102 formed on the semiconductor wafer 100 may include any digital circuits, analog circuits, RF circuits, memory, signal processor, MEMS, sensors, the like, and combinations thereof.

FIG. 2 illustrates, in a simplified cross-sectional view, the example semiconductor wafer 100 taken along line A-A at a stage of die singulation in accordance with an embodiment. At this stage, the backside of the semiconductor wafer 100 is mounted on an adhesive film 212. A portion of the semiconductor wafer 100 is depicted in FIG. 2 which includes portions of two adjacent semiconductor die 102 and singulation lane 104. The singulation lane 104 is depicted as a dashed line for illustration purposes even though a singulation lane width (e.g., 80 microns) between the adjacent semiconductor die 102 is reserved for material removal during singulation processes. Each of the semiconductor die 102 includes a seal ring 202 formed including interconnect layers in the back end of line (BEOL) region of the semiconductor wafer 100, for example. The term BEOL region as used herein refers to an upper processed region of the semiconductor wafer 100 which includes a plurality of interconnect layers (not shown) formed to interconnect transistors and the like of the semiconductor die 102. In this embodiment, the semiconductor wafer 100 has a thickness 206 of approximately 175 microns between the active side 208 and the backside 210. In other embodiments, the semiconductor wafer 100 may have a thickness in a range of 150-350 microns.

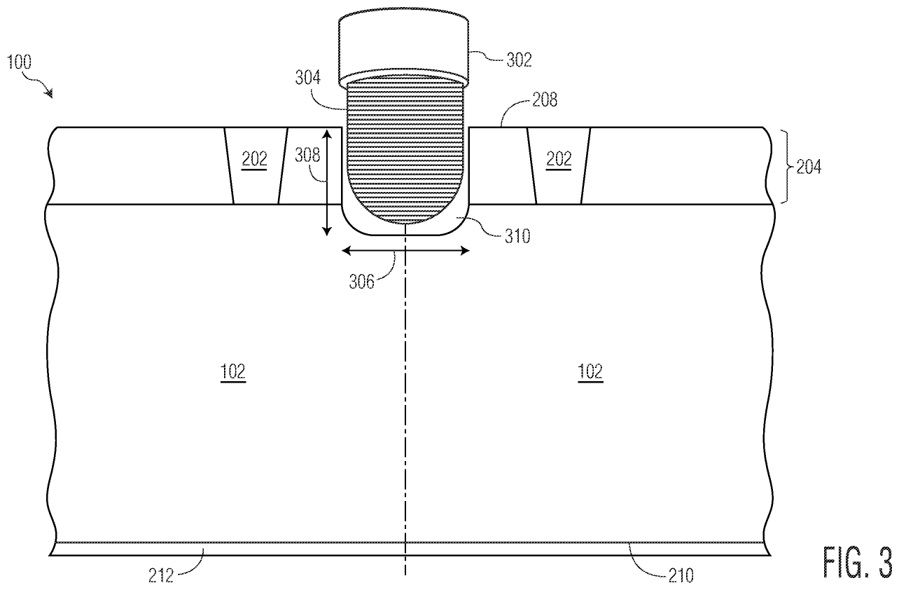

FIG. 3 illustrates, in a simplified cross-sectional view, the example semiconductor wafer 100 taken along line A-A at a subsequent stage of die singulation in accordance with an embodiment. At this stage of die singulation, a first trench 310 is formed along the singulation lanes 104 of a semiconductor wafer 100. In this embodiment, the first trench 310 is formed by way of an ultra-short pulse (USP) laser 302 and generated laser beam 304 during a first laser ablation operation. The term USP laser, as used herein, generally refers to a laser having a pulsed laser beam where the pulse durations are in the picosecond or femtosecond ranges, for example. In this embodiment, the USP laser 302 is configured to form the first trench 310 having width 306 and depth 308 dimensions while minimizing local heating to the semiconductor wafer 100 and recast in the trench. The width of the laser beam 304 is generated to correspond with the desired width 306, for example.

In this embodiment, the width 306 is predetermined based on a width of a saw blade used in a subsequent stage of die singulation and the depth 308 is predetermined based on the depth of the BEOL region 204. For example, the width 306 may be chosen to be ˜60 microns to accommodate a ˜40 micron wide saw blade. In addition, the depth 308 may be chosen to be ˜10 microns such that the first trench 310 extends below the lowest (e.g., first) metallization layer that may be located ˜8 microns below the surface of the active side 208, for example. In other embodiments, other width 306 and depth 308 dimensions may be chosen based on other saw widths and other BEOL depths.

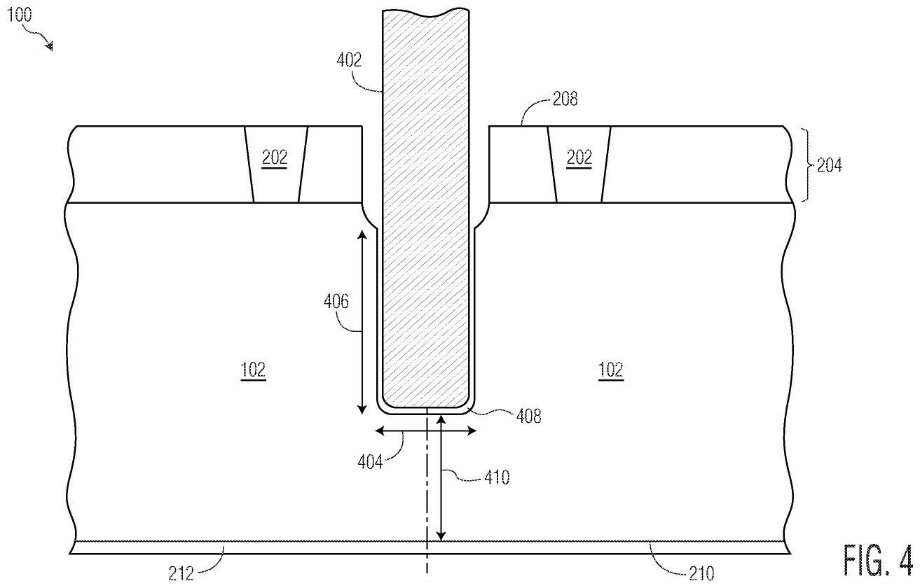

FIG. 4 illustrates, in a simplified cross-sectional view, the example semiconductor wafer 100 taken along line A-A at a subsequent stage of die singulation in accordance with an embodiment. At this stage of die singulation, a second trench 408 is formed along the singulation lanes 104 of the semiconductor wafer 100. In this embodiment, the second trench 408 is formed by way of a mechanical saw 402 during a sawing operation. A portion of the semiconductor wafer 100 having a depth 410 remains between a bottom of the second trench 408 and the backside 210 of the semiconductor wafer. In this embodiment, the mechanical saw 402 is configured to form the second trench 408 having width 404 and depth 406 dimensions. The blade of the mechanical saw 402 is narrower than the width 306 of the first trench 310 and therefore the corresponding width 404 of the second trench 408 is narrower than the width 306. By forming the second trench 408 below the BEOL region 204 and having the width 306 of the first trench 310 wider than the blade of the mechanical saw 402, mechanical smearing of the metallization layers of the BEOL region is avoided.

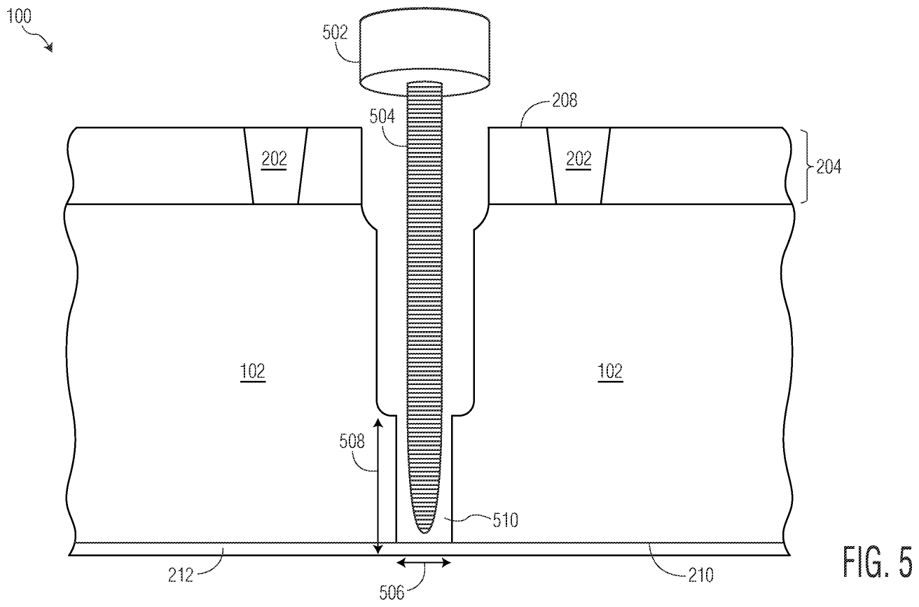

FIG. 5 illustrates, in a simplified cross-sectional view, the example semiconductor wafer 100 taken along line A-A at a subsequent stage of die singulation in accordance with an embodiment. At this stage of die singulation, a final cut 510 is formed along the singulation lanes 104 of the semiconductor wafer 100 to singulate the plurality of semiconductor die 102. In this embodiment, the cut 510 is formed by way of an USP laser 502 and generated laser beam 504 during a second laser ablation operation. The USP laser 502 is configured to form the cut 510 having width 506 and depth 508 dimensions while minimizing local heating to the semiconductor wafer 100 and recast in the cut. The width of the laser beam 504 is generated to correspond with the desired width 506 such that the width 506 is narrower than the width 404 of the second trench, for example. The depth 508 of the cut 510 extends through the portion of the semiconductor wafer remaining between the bottom of the second trench 408 and the backside 210 of the semiconductor wafer 100, thus completing singulation of the plurality of the semiconductor die 102 on the semiconductor wafer 100. In this embodiment, the USP laser 502 may be characterized as a separate laser apparatus (from the USP laser 302) to generate the laser beam 504 and thus accommodate maximum die singulation throughput. Alternatively, the USP laser 502 may be characterized as the same laser apparatus as the USP laser 302 with an alternative configuration to generate the narrower laser beam 504, for example.

In this embodiment, the width 506 is predetermined based on the width of the saw blade used in the stage of die singulation depicted in FIG. 4. For example, when a ˜40 micron wide saw blade is used to form the second trench 408, the width 506 may be chosen to be ˜30 microns to minimize the amount of material to be removed during the cut 510. In other embodiments, other width 506 dimensions may be chosen based on other saw widths, for example.

In this embodiment, after the first trench 310 is formed, the remaining depth or thickness of the semiconductor wafer is split between the sawing operation to form the second trench 408 and the second laser ablation operation to form the final cut 510. Accordingly, in some embodiments when the remaining depth is split evenly between the sawing operation and the second laser ablation operations, the depth 308 of the first trench plus the depth 406 of the second trench is greater than half of the thickness 206 of the semiconductor wafer 100.

Performing the singulation of the plurality of the semiconductor die 102 by way of the first laser ablation operation, the sawing operation, and the second laser ablation operation, as provided herein, allows for improved good die per wafer having a clean die edge without recast and eliminating yield loss due to sawing chips. For example, forming the second trench 408 below the BEOL region 204 and having the width 306 of the first trench 310 wider than the blade of the mechanical saw 402, mechanical smearing of the metallization layers of the BEOL region is avoided. And by completing the singulation process with the second laser ablation operation, mechanical sawing is limited to an intermediate region of the semiconductor wafer thickness thus preventing mechanical damage to the active side 208 or 210 backside of the plurality of the semiconductor die 102 of the semiconductor wafer 100.

Generally, there is provided, a method of semiconductor die singulation including forming a first trench along a singulation lane of a semiconductor wafer; forming a second trench along the singulation lane of the semiconductor wafer, the second trench extending from a bottom of the first trench, a portion of the semiconductor wafer remaining between a bottom of the second trench and a backside of the semiconductor wafer; and forming a cut by way of a first laser, the cut extending through the portion of the semiconductor wafer remaining between the bottom of the second trench and the backside of the semiconductor wafer to singulate die of the semiconductor wafer. The first trench may be formed on an active side of the semiconductor wafer. The first trench may extend below the back end of line (BEOL) portion of the semiconductor wafer. The second trench formed along the singulation lane of the semiconductor wafer may be formed by way of a mechanical saw. A width of the first trench may be greater than a width of the second trench. The width of the second trench may be greater than a width of the cut formed through the portion of the semiconductor wafer. The first trench formed along the singulation lane of the semiconductor wafer may be formed by way of a second laser. The first laser and the second laser each may be characterized as an ultra-short pulse laser. A depth of the first trench plus a depth of the second trench may be greater than half of a thickness of the semiconductor wafer.

In another embodiment, there is provided, a method of semiconductor die singulation including forming a first trench on an active side of a semiconductor wafer by way of a laser; forming a second trench in the semiconductor wafer, the second trench extending from a bottom of the first trench, a portion of the semiconductor wafer remaining between a bottom of the second trench and a backside of the semiconductor wafer; and forming a cut by way of the laser, the cut extending through the portion of the semiconductor wafer remaining between the bottom of the second trench and the backside of the semiconductor wafer to singulate die of the semiconductor wafer. The second trench formed in the semiconductor wafer may be formed by way of a mechanical saw. The first trench may extend below the back end of line (BEOL) portion of the semiconductor wafer. A width of the first trench may be greater than a width of the second trench. The width of the second trench may be greater than a width of the cut formed through the portion of the semiconductor wafer. The laser may be characterized as an ultra-short pulse laser. The laser may be configured to generate a first beam size when forming the first trench and configured to generate a second beam size when forming the cut, the second beam size smaller than the first beam size.

In yet another embodiment, there is provided, a method of semiconductor die singulation including forming a first trench on an active side of a semiconductor wafer by way of a first laser beam having a first beam size; forming a second trench in the semiconductor wafer by way of a mechanical saw, the second trench extending downward from a bottom of the first trench, a portion of the semiconductor wafer remaining between a bottom of the second trench and a backside of the semiconductor wafer; and forming a cut by way of a second laser beam having a second beam size, the cut extending through the portion of the semiconductor wafer remaining between the bottom of the second trench and the backside of the semiconductor wafer to singulate die of the semiconductor wafer. A width of the first trench may be greater than a width of the second trench. The width of the second trench may be greater than a width of the cut formed through the portion of the semiconductor wafer. The first laser beam and the second laser beam and may each be generated by an ultra-short pulse laser, and wherein the first beam size may be larger than the second beam size.

By now, it should be appreciated that there has been provided a semiconductor die singulation method and apparatus for improving yield and reliability. A first trench is formed at the active side of a semiconductor wafer along singulation lanes between adjacent semiconductor die. The first trench is formed by way of an ultra-short pulse (USP) laser during a first laser ablation operation. A second trench is formed along the singulation lanes of the semiconductor wafer by way of a mechanical saw during a sawing operation. A portion of the semiconductor wafer along the singulation lanes remaining between a bottom of the second trench and backside of the wafer is removed by way of a final laser cut. The final laser cut is formed by way of an USP laser configured with a narrower laser beam during a second laser ablation operation to complete the singulation process. By completing the singulation process with the second laser ablation operation, mechanical sawing is limited to an intermediate region of the semiconductor wafer thickness thus preventing mechanical damage to the active side and backside of the plurality of singulated semiconductor die. Accordingly, yield and reliability are improved.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A method of semiconductor die singulation, the method comprising:
forming a first trench along a singulation lane of a semiconductor wafer;
forming a second trench along the singulation lane of the semiconductor wafer, the second trench extending from a bottom of the first trench, a portion of the semiconductor wafer remaining between a bottom of the second trench and a backside of the semiconductor wafer; and
forming a cut by way of a first laser, the cut extending through the portion of the semiconductor wafer remaining between the bottom of the second trench and the backside of the semiconductor wafer to singulate die of the semiconductor wafer.

2. The method of claim 1, wherein the first trench is formed on an active side of the semiconductor wafer.

3. The method of claim 1, wherein the first trench extends below the back end of line (BEOL) portion of the semiconductor wafer.

4. The method of claim 1, wherein the second trench formed along the singulation lane of the semiconductor wafer is formed by way of a mechanical saw.

5. The method of claim 1, wherein a width of the first trench is greater than a width of the second trench.

6. The method of claim 5, wherein the width of the second trench is greater than a width of the cut formed through the portion of the semiconductor wafer.

7. The method of claim 1, wherein the first trench formed along the singulation lane of the semiconductor wafer is formed by way of a second laser.

8. The method of claim 7, wherein the first laser and the second laser are each characterized as an ultra-short pulse laser.

9. The method of claim 1, wherein a depth of the first trench plus a depth of the second trench is greater than half of a thickness of the semiconductor wafer.

10. A method of semiconductor die singulation, the method comprising:
forming a first trench on an active side of a semiconductor wafer by way of a laser;
forming a second trench in the semiconductor wafer, the second trench extending from a bottom of the first trench, a portion of the semiconductor wafer remaining between a bottom of the second trench and a backside of the semiconductor wafer; and
forming a cut by way of the laser, the cut extending through the portion of the semiconductor wafer remaining between the bottom of the second trench and the backside of the semiconductor wafer to singulate die of the semiconductor wafer.

11. The method of claim 10, wherein the second trench formed in the semiconductor wafer is formed by way of a mechanical saw.

12. The method of claim 10, wherein the first trench extends below the back end of line (BEOL) portion of the semiconductor wafer.

13. The method of claim 10, wherein a width of the first trench is greater than a width of the second trench.

14. The method of claim 13, wherein the width of the second trench is greater than a width of the cut formed through the portion of the semiconductor wafer.

15. The method of claim 10, wherein the laser is characterized as an ultra-short pulse laser.

16. The method of claim 10, wherein the laser is configured to generate a first beam size when forming the first trench and configured to generate a second beam size when forming the cut, the second beam size smaller than the first beam size.

17. A method of semiconductor die singulation, the method comprising:
forming a first trench on an active side of a semiconductor wafer by way of a first laser beam having a first beam size;
forming a second trench in the semiconductor wafer by way of a mechanical saw, the second trench extending downward from a bottom of the first trench, a portion of the semiconductor wafer remaining between a bottom of the second trench and a backside of the semiconductor wafer; and
forming a cut by way of a second laser beam having a second beam size, the cut extending through the portion of the semiconductor wafer remaining between the bottom of the second trench and the backside of the semiconductor wafer to singulate die of the semiconductor wafer.

18. The method of claim 17, wherein a width of the first trench is greater than a width of the second trench.

19. The method of claim 18, wherein the width of the second trench is greater than a width of the cut formed through the portion of the semiconductor wafer.

20. The method of claim 17, wherein the first laser beam and the second laser beam and each generated by an ultra-short pulse laser, and wherein the first beam size is larger than the second beam size.
